(19) United States
(12) Patent Application Publication
(10) Pub. No.: US 2024/0384400 A1
(43) Pub. Date: Nov. 21, 2024

(54) METHOD OF FORMING A RUTHENIUM-CONTAINING LAYER AND LAMINATE

(71) Applicants: L'Air Liquide, Société Anonyme pour l'Etude et l'Exploitation des Procédés Georges Claude, Paris (FR); American Air Liquide, Inc., Fremont, CA (US)

(72) Inventors: Rocio Alejandra ARTEAGA MULLER, Yokosuka (JP); Jean-Marc GIRARD, Versailles (FR); Julien GATINEAU, Versailles (FR); Venkateswara R. PALLEM, Hockessin, DE (US)

(21) Appl. No.: 18/704,365

(22) PCT Filed: Oct. 25, 2022
(86) PCT No.: PCT/US2022/047733

§ 371 Date: Apr. 24, 2024

(30) Foreign Application Priority Data
Oct. 26, 2021 (JP) 2021-174306

(51) Int. Cl. C23C 16/40; C23C 16/04; C23C 16/455; C23C 16/56; H01L 21/3205; H01L 23/532

(52) U.S. Cl. CPC C23C 16/40; C23C 16/04; C23C 16/45553; C23C 16/56; H01L 21/32051; H01L 23/53257

(57) ABSTRACT

[Purpose] To provide a method of forming a ruthenium-containing layer and a laminate, wherein the ruthenium-containing layer is selectively formed, as a protective layer capable of suppressing generation of etching residues, on a mask surface for pattern formation that is formed on a substrate, without the need for forming a selective attractant element. [Solution] A method, which comprises a preparation step of providing a substrate having an oxidizable layer, and a deposition step of depositing a ruthenium-containing layer on the oxidizable layer by using a ruthenium tetraoxide through vapour deposition, wherein the oxidizable layer contains carbon atoms.

### TECHNICAL FIELD

The present disclosure relates to a method of forming a ruthenium-containing layer and to a laminate.

BACKGROUND

In photolithography, photosensitive polymer photoresists are used to process patterned portions of thin films or bulk semiconductor substrates. After the photoresist is exposed and developed, a highly directional anisotropic reactive ion etching (hereinafter referred to as “RIE” in some places) process is performed to finally form a three-dimensional structure on the substrate. Due to the ever-increasing demands for miniaturization and increasing complexity of three-dimensional shapes in nanoelectronics, a photoresist alone may be too thin for transfer of patterns. For example, photoresists for 22 nm and thinner lithography cannot withstand high-energy ion irradiation and will degrade rapidly during RIE. To overcome this problem, materials such as amorphous carbon (hereinafter referred to as “AC” in some places) that have higher selectivity and resistance than photoresists have been introduced, and mask laminates of amorphous carbon and photoresist are formed. Ideally, the AC has the exact shape of the intended pattern provided by the photoresist in the plane of the substrate with vertical walls through the resist. Therefore, a part of the substrate will be covered with resist and AC, and the other parts will not be covered. The part of the substrate covered with resist and AC is necessary for pattern transfer as it acts as a protective layer during etching, ion injection, or other pattern transfer mechanisms.

The gradual degradation of AC is unavoidable due to the extended length of directional reactive ion etching required to form high aspect ratio structures. AC degradation due to the etching process is accelerated by ion bombardment onto the sidewall surface, which may result in an inability to ensure the shape and dimensions of the target etch layer.

Recently, carbonaceous materials such as polyamides and metal hard masks such as TiN and TaN have been introduced to reduce or eliminate the gradual degradation of AC during reactive ion etching (refer to non-patent literature 1 and 2). However, it is difficult to make these materials compatible with the patterning process because they need a selective attractant such as an inhibitor, passivator and self-assembled monolayer for selective formation onto amorphous carbon, and for reasons that a residue layer grows on the mask from the etching process or the selective formation on the mask is low, the process is not satisfactory.

### PRIOR ART DOCUMENTS

### Non-Patent Literature

Non-patent literature 1 Journal of Vacuum Science & Technology A,39, 2, 2021

Non-patent literature 2 J. Vac. Sci. Technol. B 24, 5, 2006 2262

### SUMMARY OF THE INVENTION

The purpose of the present disclosure is to provide a method of forming a ruthenium-containing layer and a laminate, wherein the ruthenium-containing layer is selectively formed, as a protective layer capable of suppressing the generation of etching residues, on a mask surface for pattern formation that is formed on a substrate, without the need for forming a selectivity attractant element.

As a result of diligent study, the inventors of the present application discovered that the above-mentioned purpose can be achieved by adopting the following configuration and thus completed the present invention.

In one embodiment, the present disclosure relates to a method of forming a ruthenium-containing layer, comprising

a preparation step of preparing a substrate having an oxidizable layer, and

a deposition step of depositing the ruthenium-containing layer onto the oxidizable layer by using a ruthenium tetraoxide through vapour deposition,

wherein the oxidizable layer comprises carbon atoms.

With this formation method, a ruthenium-containing layer can be selectively deposited on the oxidizable layer of a substrate with the oxidizable layer (i.e., a layer having the property of being oxidized). Ruthenium (Ru) is resistant to oxidation, nitridation, and many plasma chemical substances (e.g., perfluorocarbon (PFC) gases, etc.) typically used to etch coated layers such as anti-reflective coating layer. At the same time, ruthenium can be easily removed without generating residues by other plasma chemicals that do not remove coating layer materials. Therefore, during etching, the ruthenium-containing layer acts as a protective layer for the oxidizable layer such as the pattern mask. As a result, mask degradation can be avoided and residue formation can be reduced without the need for an inhibitor or self-assembled monolayer (SAM). Furthermore, the risks of pattern clogging and collapse can be reduced. Although the reason for that is not clear, it is assumed that one reason is that the ruthenium tetraoxide (RuO₄) is a strong oxidizing agent that can also be used for gas-phase reactions and has a kind of affinity with the oxidizable layer.

Further, the oxidizable layer preferably contains carbon atoms. When the oxidizable layer contains oxidizable carbon atoms or carbon-carbon bonds (that is, by being an organic layer or a semi-organic layer), the affinity between the ruthenium tetraoxide and the oxidizable layer is further improved. As a result, the selective formation of the ruthenium tetraoxide layer on the oxidizable layer can be further enhanced.

In one embodiment, the average composition of the ruthenium-containing layer may be RuOx. Here, the value of x is 0 or more but not more than 2. Also, when the value of x is 0 (including substantially 0), it means that a pure ruthenium layer is formed. Here, the average composition is determined from the average by X-ray photoelectron spectroscopy. Specifically, X-ray photoelectron spectroscopy is repeated to obtain 3 sets of data, and the average composition can be calculated from the average of them.

In one embodiment, the thickness of the ruthenium-containing layer formed per cycle of the deposition process is preferably 0.05 nm or more but not more than 0.20 nm. Further, in one embodiment, the ruthenium-containing layer formed by the deposition step preferably has a thickness of 1 nm or more but no more than 30 nm. In this way, the mask protection function, strength and productivity of the ruthenium-containing layer can be highly balanced.

In one embodiment, the forming method comprises, in the deposition step, a deposition cycle comprising a 1st exposure of exposing the ruthenium tetraoxide to the oxidizable layer, and a 2nd exposure of exposing at least one co-reactant selected from the group consisting of hydrogen gas, ammonia gas, and hydrazine to the oxidizable layer after the 1st exposure, with said deposition cycle preferably being performed once or twice or more. In the deposition process, under the action of the ruthenium tetraoxide, the carbon-carbon bonds in the oxidizable layer are converted into oxidizing groups such as epoxies, aldehydes, ketones, etc., and at the same time, ruthenium oxide species such as RuO₂ are produced. Then, by reducing the oxidizing groups and ruthenium tetraoxide species with a co-reactant such as hydrogen gas, along with the reduction of the oxidizing groups bonded to the oxidizable layer, deposition of a layer containing ruthenium with an average composition of RuOx (where the value of x is 0 or more but not more than 2) is possible.

In one embodiment, the substrate preferably further comprises an oxide layer. Since ruthenium tetraoxide does not exhibit reactivity with oxide layers that do not have the property of being oxidized, it is possible to further enhance the selective formation of a ruthenium-containing layer onto the oxidizable layer.

In one embodiment, the oxide layer may be an SiO₂ layer, SiN layer, SiON layer, Al₂O₃ layer, ZrO₂ layer, TiO₂ layer or HfO₂ layer. An appropriate oxide layer may be arranged depending on the intended use of the substrate.

In one embodiment, the oxidizable layer is preferably an amorphous carbon layer, a boron-doped amorphous carbon layer, a tungsten-doped amorphous carbon layer, a photoresist layer, or a porogen-containing porous low-k precursor layer. An amorphous carbon layer and a photoresist layer typically contain oxidizable sp² carbon atoms condensed as aromatic clusters or linked to other fragments or heteroatoms. Also, the porogen-containing porous low-k precursor layer has functional groups such as sp² and sp³ carbon atoms or C—H bonds that have a strong affinity for oxidation. Therefore, these oxidizable layers can exert affinity for oxidation reaction by a ruthenium tetraoxide. As a result, it is possible to further enhance the selective formation of the ruthenium-containing layer. Here, the amorphous carbon layer means a layer substantially composed of amorphous carbons (alone). A boron-doped amorphous carbon layer means a layer composed of amorphous carbons doped with boron. A tungsten-doped amorphous carbon layer means a layer composed of amorphous carbons doped with tungsten.

In one embodiment, the oxidizable layer is preferably an amorphous carbon layer.

In one embodiment, the oxidizable layer may be patterned. Even if the oxidizable layer has the shape of line-and-space or a contact hole, a ruthenium tetraoxide layer can be selectively formed as a protective layer to protect the oxidizable layer.

In another embodiment, the present disclosure relates to a method of forming a ruthenium-containing layer,

comprising a preparation step of placing a substrate having an oxidizable layer in a deposition chamber, and

a deposition step, wherein, by a vapour deposition method, vaporized ruthenium tetraoxide is introduced into the deposition chamber, and a ruthenium-containing layer is deposited onto the oxidizable layer,

wherein the oxidizable layer comprises carbon atoms.

In another embodiment, the present disclosure relates to a method of forming a ruthenium-containing layer,

a preparation step of preparing a substrate having an oxidizable layer, and

a deposition step, wherein ruthenium tetraoxide is deposited by a vapour deposition method to form a ruthenium-containing film onto the oxidizable layer,

wherein the oxidizable layer comprises carbon atoms.

In another embodiment, the present disclosure relates to a method of forming a ruthenium-containing layer,

a substrate having a surface with an oxidizable layer and an oxide layer, and

a ruthenium-containing layer formed on the surface of the oxidizable layer,

wherein the oxidizable layer comprises carbon atoms.

In the laminate, since the ruthenium-containing layer is selectively formed as a protective layer on the surface of the oxidizable layer, the oxide layer can be efficiently subjected to etching or the like while preventing deterioration of the layer to be oxidized.

The oxidizable layer preferably contains carbon atoms. As the oxidizable layer contains oxidizable carbon atoms or carbon-carbon bonds, the affinity between ruthenium tetraoxide and the oxidizable layer is further improved, and the selective formation of the ruthenium-containing layer on the oxidizable layer can be further enhanced.

In another embodiment, the oxidizable layer is preferably an amorphous carbon layer, a boron-doped amorphous carbon layer, a tungsten-doped amorphous carbon layer, a photoresist layer, or a porogen-containing porous low-k precursor layer. Of them, preferably the oxidizable layer is an amorphous carbon layer. These oxidizable layers have oxidizable carbon atoms and can exert affinity for the oxidation reaction of ruthenium tetraoxide to further enhance the selective formation of the ruthenium-containing layer.

In another embodiment, the ruthenium-containing layer preferably has a thickness of 1 nm or more but no more than 30 nm. In this way, the mask protection function, strength and productivity of the ruthenium-containing layer can be highly balanced.

### BRIEF DESCRIPTION OF THE DRAWINGS

For a further understanding of the nature and objects for the present invention, reference should be made to the following detailed description, taken in conjunction with the accompanying drawings, in which like elements are given the same or analogous reference numbers and wherein:

FIG. 1A is a schematic cross-sectional view showing a step in the method of forming a ruthenium-containing layer according to one embodiment.

FIG. 1B is a schematic cross-sectional view showing a step in the method of forming a ruthenium-containing layer according to one embodiment.

FIG. 1C is a schematic cross-sectional view showing a step in the method of forming a ruthenium-containing layer according to one embodiment.

FIG. 1D is a schematic cross-sectional view showing a step in the method of forming a ruthenium-containing layer according to one embodiment.

FIG. 2 is a schematic diagram showing an assumed mechanism of a series of reactions on the surface of an organic carbonaceous layer from the formation to the removal of a ruthenium-containing layer.

FIG. 3A is an electron micrograph (magnification: ×120,000) of a ruthenium-containing layer containing ruthenium alone that is formed on the surface of the amorphous carbon layer in Example 1.

FIG. 3B is an electron micrograph (magnification: ×100,000) of the surface of the SiO₂ layer in Example 1.

FIG. 4 is a secondary ion mass spectrometry chart of a ruthenium-containing layer containing ruthenium alone that is formed on the surface of an amorphous carbon layer.

### DETAILED DESCRIPTION OF PREFERRED EMBODIMENTS

Embodiments of the present disclosure will be described below. The present invention is not limited to these embodiments

### Method of Forming a Ruthenium-Containing Layer

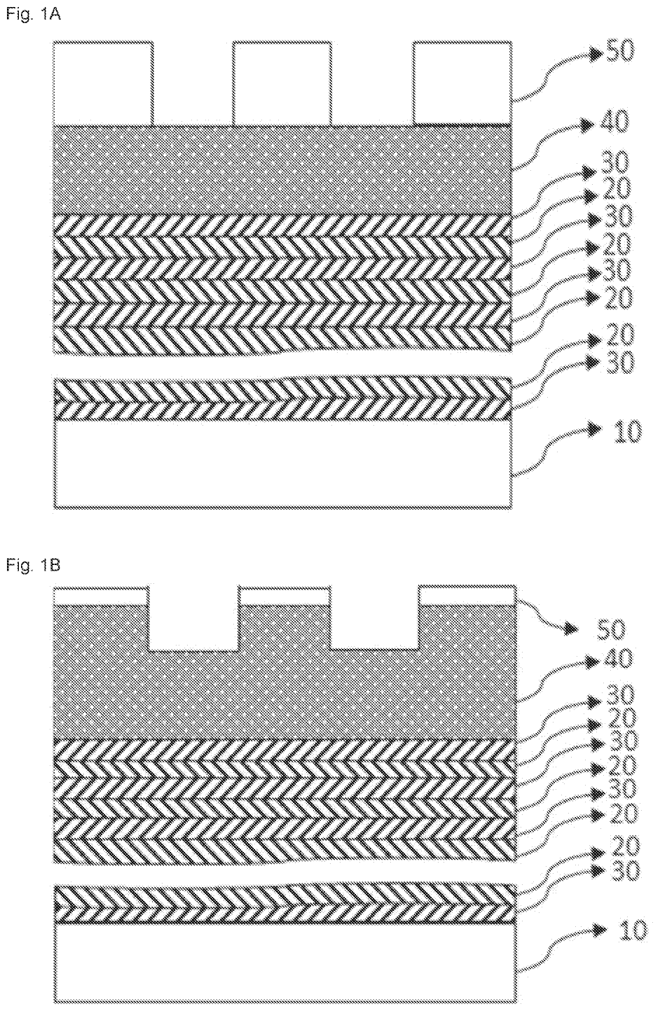

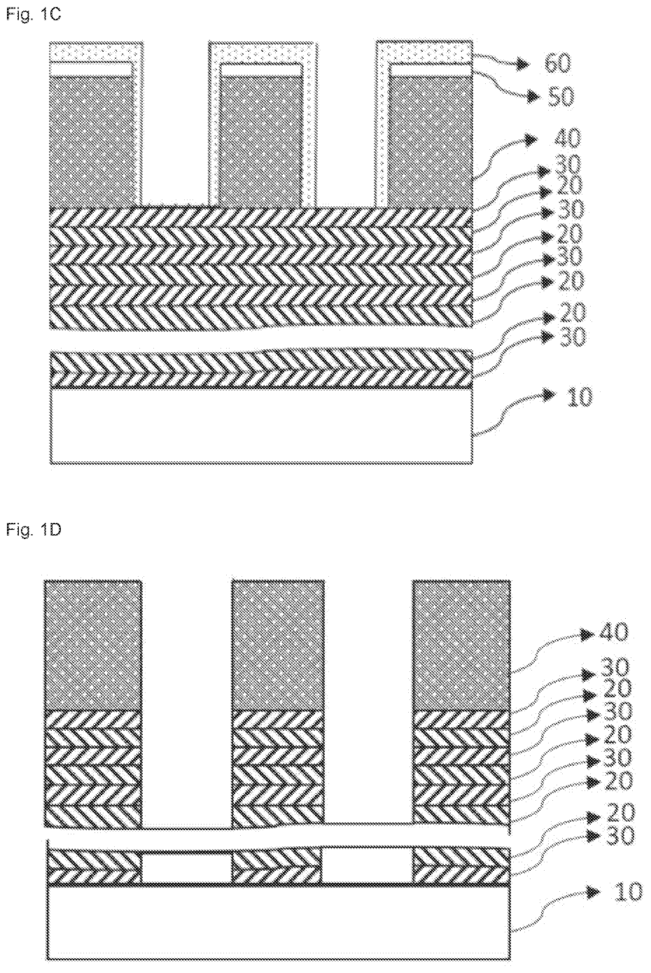

A method of forming a ruthenium-containing layer according to the present embodiment includes a preparation step of preparing a substrate having an oxidizable layer, and a deposition step of depositing a ruthenium-containing layer onto the oxidizable layer by using ruthenium tetraoxide through vapour deposition. Below, referring to FIG. 1A to FIG. 1D, an example of forming, as an oxidizable layer, a laminate of a carbonaceous hard mask and a resist film onto a substrate, and after patterning, forming, as a protective layer, a ruthenium-containing layer onto the surface of the laminate is used to describe the individual steps.

FIG. 1A to FIG. 1D are schematic cross-sectional views showing a step of the method of forming a ruthenium-containing layer according to one embodiment.

### Preparation Step

In this step, a substrate having an oxidizable layer is prepared. As shown in FIG. 1A, on a semiconductor layer 10 as a substrate, a hard mask laminate (hereinafter sometimes referred to as an “ONON (oxide-nitride-oxide-nitride-nitride) laminate”) that is laminated by alternating between a sacrificial layer 20 (e.g., SiN layer) and an isolating layer 30 (e.g., SiO₂ layer) is formed. The number of layers that are laminated is set as appropriate depending on the intended use of the substrate. The ONON laminate can be formed by the CVD (Chemical Vapour Deposition) method or the ALD (Atomic Layer Deposition) method.

The substrate may be selected from oxides (e.g. HfO₂-based material, TiO₂-based material, ZrO₂-based material, rare earth oxide-based material, ternary oxide-based material, etc.) used as insulating materials in MIM, DRAM, or FeRam technology or may be selected from nitride-based films (e.g., TaN) used as oxygen barriers between copper-based substrates or between a low-k film and a copper-based substrate. In the manufacture of semiconductors, photovoltaic cells, LCD-TFTs or flat panel devices, other substrates may be used. Examples of such substrates include, but are not limited to, metal nitride-containing substrates (e.g., TaN, TiN, SiN, WN, TaCN, TiCN, TaSiN, and TiSiN), etc.; insulators (e.g., SiO₂, Si₃N₄, SiON, HfO₂, Ta₂O₅, ZrO₂, TiO₂, Al₂O₃, and barium strontium titanate); or other substrates containing one of combinations of these materials.

Next, an organic carbonaceous layer 40 such as amorphous carbon is deposited on the ONON laminate. The organic carbonaceous layer 40 has an interface with the insulating layer 30 at the bottom. The organic carbonaceous layer can be deposited, for example, by CVD.

A resist composition is coated onto the organic carbonaceous layer 40 to form a resist film, and the resist film is patterned to form a resist pattern 50. The resist pattern 50 is used, for example, to form line-and-space patterns and contact holes as a part of three-dimensional memory structures.

As shown in FIG. 1B, the resist pattern 50 is used to treat the organic carbonaceous layer 40 after the 1st etching step, which consists of reactive ion etching (RIE). The organic carbonaceous layer 40 and the resist pattern 50 are anisotropically etched, and the film thickness of the two layers is reduced. The corresponding parts between holes or patterns in the organic carbonaceous layer 40 are etched until the insulating layer 30 of the ONON laminate is exposed. In this way, a substrate having an oxidizable layer can be manufactured.

The substrates are not limited to those mentioned in the above. For example, many metals, i.e., transition metals, can occur in several different oxidation states. This means that they have the ability to be oxidized to form oxides. In addition, surfaces with C—H bonds, Si—Si bonds, Si—H bonds, Ge—Ge bonds and Ge—H bonds are also suitable for selective formation. Therefore, the formation of a protective layer by selective vapour deposition can be applied to a wide variety of substrates provided that ruthenium tetraoxide is exposed to the oxidized surface.

### Deposition Step

In this step, a ruthenium-containing film is deposited on the oxidizable layer by using ruthenium tetraoxide through vapour deposition. To form holes or patterns passing through the organic carbonaceous layer 40 and the ONON laminate to arrive at the semiconductor layer 10, longer lengths of time are required for etching. Conventionally, during this process, the formation of residues from the resist pattern 50 and the organic carbonaceous layer 40 is promoted, and the residues go into non-through holes or between patterns, thus increasing the risks of clogging between holes or patterns. Further, holes or patterns deform during ion bombardment of the surfaces of the resist pattern 50 and the organic carbonaceous layer 40, and their shape features or structures collapse.

In contrast, in the present embodiment, to avoid formation of polymer particles during the subsequent plasma etching step of the ONON laminate and other anti-reflection coating layers (not shown), a material more resistant to the etching gas is used. Specifically, as shown in FIG. 1C, instead of depositing ruthenium on the insulating layer 30 located at the bottom of the ONON laminate, ruthenium tetraoxide (RuO₄) is selectively deposited on the surfaces of both the resist pattern 50 and the organic carbonaceous layer 40 by vapour deposition to form ruthenium-containing layers to protect them. At this time, the ruthenium tetraoxide reacts with the organic carbonaceous layer 40 to oxidize the surface layer thereof. The ruthenium tetraoxide can be accompanied by a solvent (e.g., a fluorinated solvent or tetrahydrofuran).

Preferably, the ALD method or CVD method may be adopted as the vapour deposition method. To remove contaminants from the substrate, a pretreatment step including oxygen plasma exposure for 1 to 10 seconds may be performed. The deposition chamber may be any sealed container or chamber of a device in which the vapour deposition method is carried out. Examples of deposition chambers include, but are not limited to, a parallel plate type reactor, cold wall type reactor, hot wall type reactor, single plate reactor, multi-wafer reactor, or other types of deposition systems.

Next, a gas containing vaporized ruthenium tetraoxide is introduced into the deposition chamber. Pure ruthenium tetraoxide (alone) or ruthenium tetraoxide blended with other components may be supplied to the vaporizer in the liquid state. It is vaporized by bubbling the carrier gas before being introduced into the deposition chamber. If necessary, the container may be heated to a temperature at which the ruthenium tetraoxide has a sufficient vapour pressure and which is below its decomposition temperature. The carrier gas can be, but is not limited to, Ar, He, N₂, and a mixture thereof. The container may be maintained, for example, at a temperature in the range of preferably 50° C. to 300° C., more preferably 80° C. to 200° C.

The ruthenium tetraoxide in the deposition chamber may be maintained at a pressure preferably in the range of 0.1 Pa to 2 Pa, more preferably 0.2 Pa to 1.5 Pa.

The ruthenium tetraoxide can be supplied as a pure substance (e.g., a liquid or a low melting-point solid) or in a state of being blended with a suitable solvent. The solvent may be a non-flammable solvent or a flammable solvent. The solvent may be, for example, methylethyl fluorinated solvent, tetrahydrofuran, and the like. In addition, a mixture solvent of various solvents may be used.

The lower limit of the thickness of the ruthenium oxide layer formed per cycle of the deposition step is preferably 0.05 nm, more preferably 0.10 nm, and further more preferably 0.15 nm. The upper limit of the thickness per cycle of the deposition step is preferably 0.30 nm, more preferably 0.25 nm, still more preferably 0.20 nm.

The lower limit of the thickness of the ruthenium-containing layer formed by the deposition step is preferably 1 nm, more preferably 2 nm, further more preferably 4 nm, and particularly preferably 5 nm. The upper limit of the thickness of the ruthenium oxide layer is preferably 30 nm, more preferably 28 nm, yet more preferably 26 nm, and particularly preferably 24 nm.

In the deposition step, preferably the deposition cycle comprising a 1st exposure of exposing the ruthenium tetraoxide to the oxidizable layer, and after the 1st exposure, a 2nd exposure of exposing at least one co-reactant selected from the group consisting of hydrogen gas, ammonia gas, and hydrazine to the oxidizable layer after the 1st exposure is repeated 1 or 2 times or more. Through a co-reactant such as hydrogen gas, a layer of RuOx (where x is between 0 and 2) can be deposited while the oxidizing groups bonded to the oxidizable layer are reduced.

Therefore, in the process of the ALD method for depositing a ruthenium-containing layer, one deposition cycle includes a step of exposing the substrate to a 1st reactant, a step of removing any unreacted 1st reactant and reaction by-products from the reaction space, a step of exposing the substrate to a 2nd reactant, and a subsequent 2nd removal step. For example, the 1st reactant can include a ruthenium tetraoxide (RuO₄), and the 2nd reactant can include hydrogen (H₂) gas. This one deposition cycle may be repeated until the desired ruthenium-containing layer is obtained.

Preferably, the hydrogen gas as a co-reactant is introduced into the deposition chamber along with a carrier gas. This carrier gas is preferably the carrier gas that is used for introducing the ruthenium tetraoxide. Of them, it is preferably argon (Ar).

The lower limit of the percentage of the volume of the hydrogen gas in the total volume of the hydrogen gas and argon gas is preferably 5%, more preferably 10%, and further more preferably 15%. The upper limit of the percentage of the hydrogen gas by volume is preferably 90%, more preferably 50%, and further more preferably 30%.

Further, the percentage of hydrogen gas may be 100%. Furthermore, nitrogen gas may be used instead of argon gas.

The partial pressure of the hydrogen gas in the deposition chamber can be maintained at a pressure preferably in the range of 100-800 Pa, and more preferably in the range of 200-600 Pa.

After a ruthenium-containing layer (a ruthenium-containing layer or a pure ruthenium layer with an average composition of RuOx (where the value of x is 0 or more but not more than 2)) is deposited as a protective layer on both of the surfaces of the organic carbonaceous layer 40 and the resist pattern 50, the sacrificial template can then be transferred to the substrate without accumulating residues on the sidewalls of the pattern from further etching, as shown in FIG. 1D.

The ruthenium-containing layer is converted to a ruthenium tetraoxide (RuO₄) layer without leaving residues by nitrides, oxides, and other plasma chemicals such as oxygen plasma that do not remove the ARC material. This ruthenium oxide layer can be easily purged from the deposition chamber and easily removed.

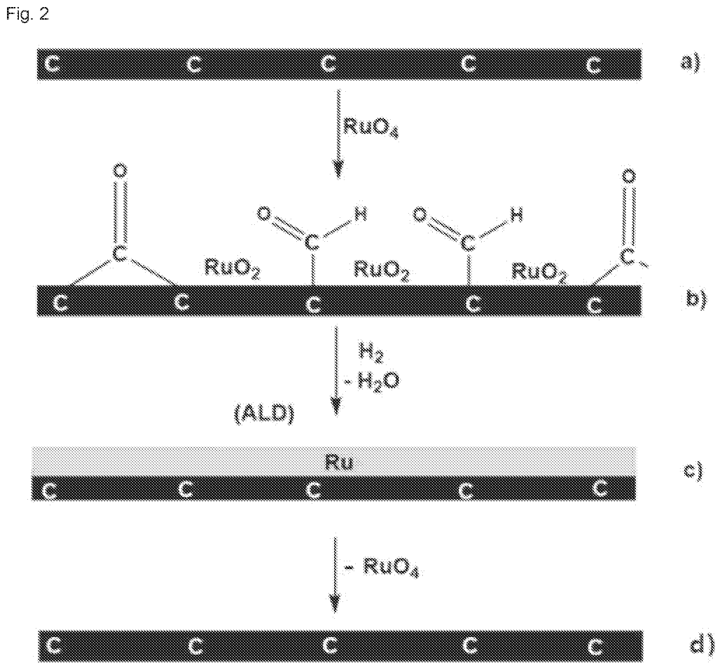

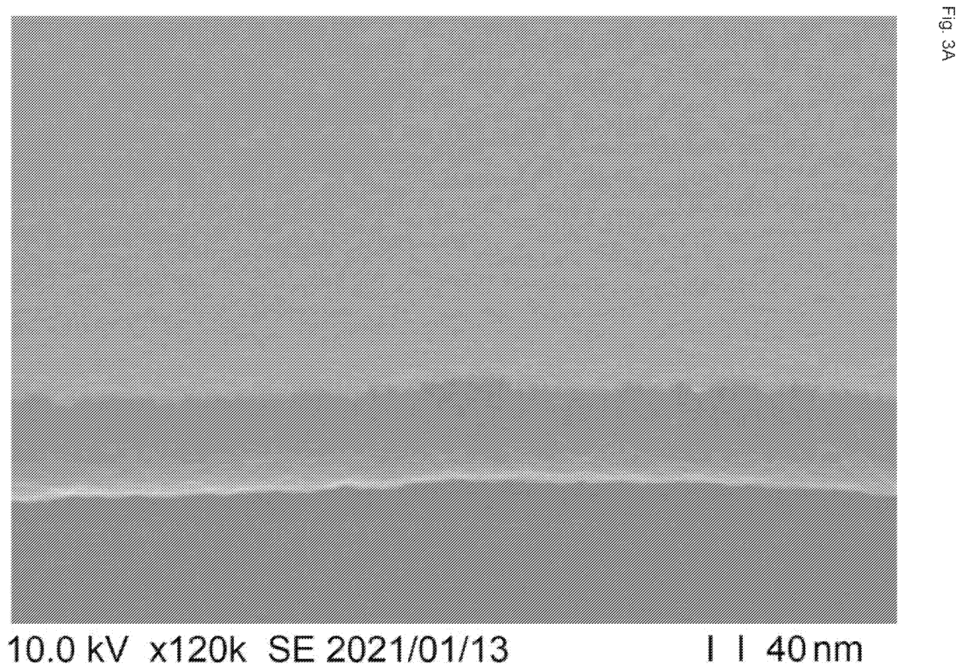

FIG. 2 shows an assumed mechanism of a series of reactions on the surface of the organic carbonaceous layer from formation up to removal of the ruthenium-containing layer. However, the present invention is not limited to this assumed mechanism.

The surface of the oxidizable layer (for example, the organic carbonaceous layer 40) formed on the substrate has carbon atoms (state as shown in FIG. 2).

Through oxidation of the surface of the organic carbonaceous layer 40 by a

ruthenium tetraoxide (RuO₄), the carbon atoms and carbon-carbon bonds are converted into oxidizing groups such as epoxies, aldehydes, and ketones while ruthenium oxide species such as RuO₂ are generated (state b shown in FIG. 2).

Next, during reduction by hydrogen gas as a co-reactant, a pure ruthenium layer is deposited while the oxygen-containing functional groups bonded to the organic carbonaceous layer 40 are reduced (state c shown in FIG. 2).

Thereafter, the ruthenium-containing layer (ruthenium layer) is treated with oxygen plasma to form a ruthenium tetraoxide (RuO₄) layer and purged to remove the ruthenium-containing layer from the surface of the organic carbonaceous layer 40 (stated shown in FIG. 2).

With respect to the plasma cleaning conditions for removing the ruthenium layer, the oxygen gas pressure is preferably from 0.1 Pa to 1.5 Pa, and more preferably 0.2 Pa to 1.0 Pa. The power is preferably from 100 W to 500 W, and more preferably from 200 W to 300 W.

The plasma treatment time is preferably from 1 second to 50 seconds, more preferably from 5 seconds to 20 seconds.

### Other Oxidizable Layers

When the material is less reactive to oxidation or not that reactive to oxidation and therefore less reactive to a ruthenium tetraoxide (RuO₄), those skilled in the art will recognize that by modifying or introducing oxide functional groups in the layer to be protected, it is possible to achieve selective formation of a ruthenium-containing layer. For example, some already oxidized or unreacted low-k or ULK layers, when filled with sacrificial organic porogens (e.g., BCHD or ATRP) before being exposed to ultraviolet light required for making them porous, may become reactive to a ruthenium tetraoxide (RuO₄).

Organic carbonaceous porogen materials have functional groups such as sp²and sp³ carbon-carbon bonds, carbon-hydrogen bonds, etc., which have strong affinities for oxidation. Thus, a ruthenium tetraoxide (RuO₄) as a strong oxidant can selectively react with an organic carbonaceous porogen material to selectively deposit a ruthenium-containing layer as a protective layer.

### Laminate

A laminate according to the present embodiment includes a substrate having an oxidized surface and an oxide layer, and a ruthenium-containing layer formed on the surface of the oxidizable layer, wherein the oxidizable layer contains carbon atoms. Such a structure corresponds to the structure of FIG. 1C shown in the description of the method of forming a ruthenium-containing layer (in FIG. 1C, although the ruthenium-containing layer is a ruthenium layer, the present invention is not limited to this, and the average composition may be RuOx (the value of x is from 0 to 2)). Therefore, reference is made to the corresponding parts of the above description, which has been provided by referring to FIG. 1A-FIG. 1D and FIG. 2, for preferred modes of the individual elements.

### Other Embodiments

One embodiment of the present invention relates to a method and to a precursor useful for manufacturing electronic devices. More particularly, it relates to depositing a ruthenium film on a substrate. The present invention relates to a method of protecting a layer in an etching process that involves multiple patterning and self-alignment techniques for forming contacts, vias, memory holes and other stacked layers.

One embodiment of the present invention relates to the use of a ruthenium precursor containing RuO₄ for selectively depositing ruthenium or a ruthenium-containing film on an organic or a semi-organic layer but not on an inorganic layer.

A Ru film is selectively deposited by chemical vapour deposition (CVD) or atomic layer deposition (ALD) on an organic or a semi-organic carbonaceous layer without the need for an inhibitor or a self-assembled monolayer (SAM), and then the film acts as an etch hard mask in subsequent etching steps for patterning a target layer. The ruthenium layer produced by this method is also used to reduce the spacing between lines of an organic or semi-organic layer, thus providing an effect of oppositely trimming the transferred pattern structure.

One embodiment of the present invention relates to a method for efficiently forming structures with improved mechanical strength in logics, transistors and memory devices as compared to multiple patterning and self-alignment patterning techniques. The ruthenium-containing layer deposited by this method is deposited on selected areas on a substrate to act as a protective hard mask layer for preventing damage to the hard mask during the etching process, which is a step in lithography.

### EXAMPLES

Although the examples are provided below to illustrate the application of the disclosure in the description, it should be understood that a particular embodiment or group of embodiments of the present invention may not include all the advantages of the processes introduced in the description. Although particular embodiments and examples are disclosed below, it should be understood that the present invention may be extended beyond the specifically disclosed embodiments and/or uses of the present invention, including obvious modifications made by those skilled in the art. Accordingly, it should be understood that the scope of the disclosed invention should not be limited by the particular embodiments described below.

### Example 1

A substrate with an SiO₂ layer (thickness of 3 μm) and an amorphous carbon layer (thickness of 700 nm, contact holes with a diameter of 140 to 160 nm are formed at intervals of 100 nm) sequentially formed on the surface was prepared (purchased from Advantec Co., Ltd). This substrate was placed in a chamber heated to a temperature below the decomposition temperature of the ruthenium tetraoxide (RuO₄) (100° C.), and a cycle of the ALD method of passing the ruthenium tetraoxide vapour through the chamber was performed. The cycle conditions were that RuO₄ was pulsed into the chamber at 0.8 Pa for 10 s, and the excessive unreacted gas was purged from the chamber. Next, a hydrogen gas (20% H₂/Ar (ratio by volume)) at a partial pressure of 500 Pa was added as a co-reactant for 10 seconds for the reduction of the ruthenium oxide layer during the surface reaction to form a ruthenium layer (an average composition of RuOx, where x=0).

According to the above method, in one cycle, the thickness of the ruthenium layer had a growth rate ranging from 0.07 nm to 0.19 nm.

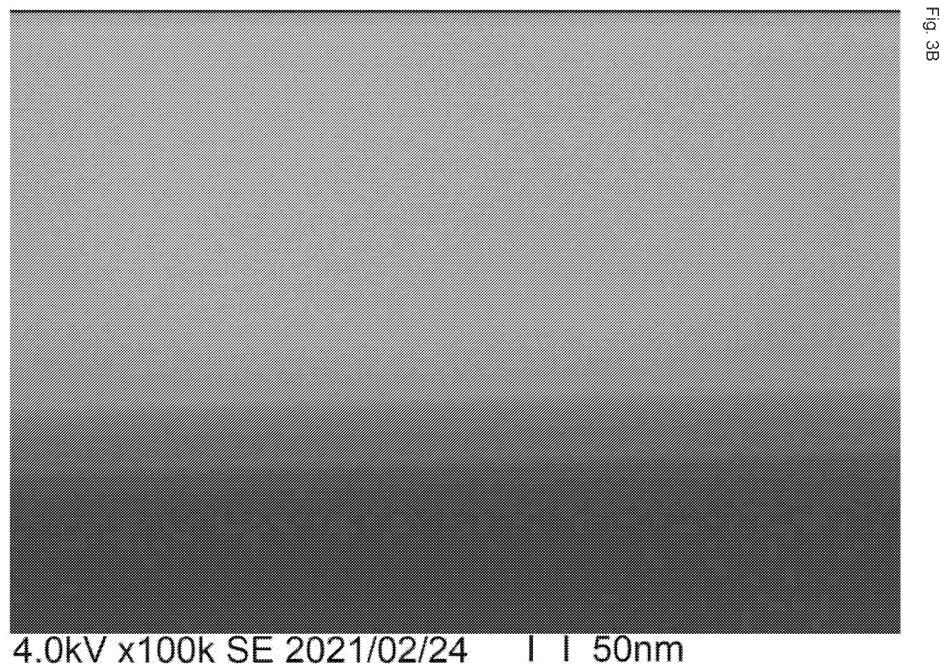

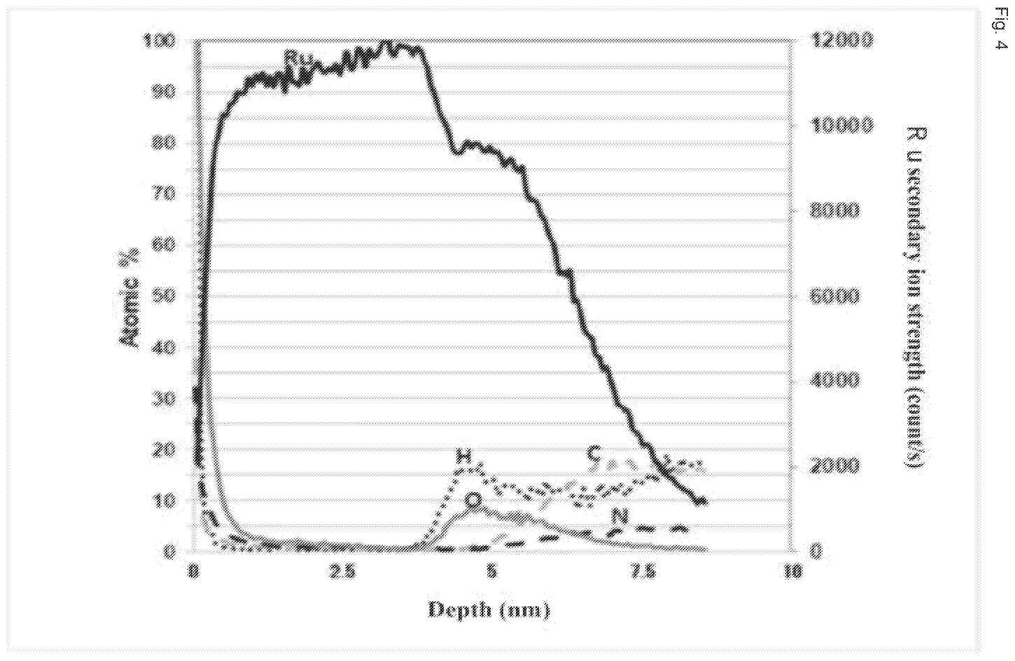

As a result, after 30 cycles of the ALD method, a ruthenium layer of 2.30 nm was selectively deposited on the amorphous carbon layer. On the other hand, no ruthenium layer was deposited on the SiO₂ layer. FIG. 3A is an electron microscopy image (magnification: ×120,000) of a ruthenium-containing layer containing ruthenium alone formed on the surface of an amorphous carbon layer. FIG. 3B is an electron microscopy image (magnification: ×100,000) of the surface of the SiO₂ layer. Hitachi UHR FE-SEM SU9000 manufactured by Hitachi High-Tech Co., Ltd. was used as an electron microscope.

FIG. 4 is a secondary ion mass spectrometry chart of a ruthenium-containing layer containing ruthenium alone formed on the surface of an amorphous carbon layer. A PHI ADEPT1010 manufactured by ULVAC-Phi, Inc. was used for the secondary ion mass spectrometry. The measurement conditions are as follows.
Primary ion species: Cs⁺
Primary acceleration voltage: 2.0 kV
Detection area: 132×132 (μm×μm)

The measurement results are shown in FIG. 4. The horizontal axis in FIG. 4 represents the depth (nm) from the surface, and the vertical axis represents the ratio (%) of each element. It can be seen that ruthenium alone existed from the surface of the ruthenium-containing layer to a depth of about 4 nm and that a highly pure ruthenium layer was formed.

The plasma cleaning conditions for the removal of the ruthenium layer were 5 pulses of O₂ plasma over 10 seconds at a pressure of 0.5 Pa and a power of 250 W by using an O₂ gas with a purity of 99.999%.

### Example 2

Same as in Example 1, after 60 cycles of the ALD method, a ruthenium layer of 8.44 nm was selectively deposited on the amorphous carbon layer. On the other hand, no ruthenium layer was deposited on the SiO₂ layer.

### Example 3

Same as in Example 1, after 120 cycles of the ALD method, a ruthenium layer of 22.48 nm was selectively deposited on the amorphous carbon layer. On the other hand, no ruthenium layer was deposited on the SiO₂ layer.

### DESCRIPTION OF SYMBOLS

10 Semiconductor layer
20 Sacrificial layer (SiN layer)
30 Insulating layer (SiO₂ layer)
40 Organic carbonaceous layer (amorphous carbon layer)
50 Resist pattern
60 Ruthenium-containing layer (ruthenium layer)

It will be understood that many additional changes in the details, materials, steps and arrangement of parts, which have been herein described in order to explain the nature of the invention, may be made by those skilled in the art within the principle and scope of the invention as expressed in the appended claims. Thus, the present invention is not intended to be limited to the specific embodiments in the examples given above.

1. A method of depositing a Ruthenium-containing layer onto a substrate having an oxidizable surface layer and an oxide surface layer, the method comprising: a step of depositing the ruthenium-containing layer onto the oxidizable surface layer by using a ruthenium tetraoxide through a vapour deposition process, while not depositing the ruthenium-containing layer onto the oxide surface layer
wherein the oxidizable surface layer comprises carbon atoms.

2. The method of forming a ruthenium-containing layer according to claim 1, wherein an average atomic composition of the ruthenium-containing layer is RuOx (in which the value of x is from 0 to 2).

3. The method of forming a ruthenium-containing layer according to claim 1, wherein the step of depositing the ruthenium-containing layer is repeated in cycles and a thickness of the ruthenium-containing layer formed in each cycle of the deposition step is 0.05 nm or more but no more than 0.30 nm.

4. The method of forming a ruthenium-containing layer according to claim 1, wherein the final thickness of the ruthenium-containing layer formed in the deposition step(s) is from 1 nm to 30 nm.

5. The method of forming a ruthenium-containing layer according to claim 1, wherein, the deposition step(s) comprise a 1st exposure of exposing the ruthenium tetraoxide to the oxidizable layer, and after the 1st exposure, a 2nd exposure of exposing at least one co-reactant to the oxidizable layer after the 1st exposure, wherein the at least one co-reactant is selected from a group consisting of hydrogen gas, ammonia gas, and hydrazine.

6. The method of forming a ruthenium-containing layer according to claim 1, wherein the oxide surface layer is an SiO₂ layer, SiON layer, Al₂O₃ layer, ZrO₂ layer, TiO₂ layer or HfO₂ layer.

7. The method according to claim 1, wherein the oxidizable surface layer is an amorphous carbon layer, a boron-doped amorphous carbon layer, a tungsten-doped amorphous carbon layer, a photoresist layer or a porogen-containing porous low-k precursor layer.

8. The method of forming a ruthenium-containing layer according to claim 7, wherein the oxidizable layer is an amorphous carbon layer.

9. The method of forming a ruthenium-containing layer according to claim 1, wherein the oxidizable layer is patterned.

10. A substrate having a surface with an oxide surface layer, and a ruthenium-containing surface layer directly on anoxidizable layer, wherein the oxidizable surface layer contains carbon atoms.

11. The substrate according to claim 10, wherein an average atomic composition of the ruthenium-containing layer is RuOx (in which the value of x is from 0 to 2).

12. The substrate according to claim 10, wherein the oxidizable surface layer is an amorphous carbon layer, a photoresist layer, a boron-doped amorphous carbon layer, a tungsten-doped amorphous carbon layer or a porogen-containing porous low-k precursor layer.

13. The substrate according to claim 12, wherein the oxidizable layer is an amorphous carbon layer.

14. The substrate according to claim 10, wherein the thickness of the ruthenium-containing layer is from 1 nm to 30 nm.
